(19) United States
(12) Patent Application Publication
(10) Pub. No.: US 2021/0227704 A1
(43) Pub. Date: Jul. 22, 2021

(54) FLEXIBLE DISPLAY SCREEN SUPPORT STRUCTURE

(71) Applicant: Wuhan China Star Optoelectronics Semiconductor Display Technology Co., Ltd., Wuhan (CN)

(72) Inventors: Wei BI, Wuhan (CN); Zikang FENG, Wuhan (CN)

(73) Assignee: Wuhan China Star Optoelectronics Semiconductor Display Technology Co., Ltd., Wuhan (CN)

(21) Appl. No.: 16/630,439

(22) PCT Filed: Apr. 16, 2019
(86) PCT No.: PCT/CN2019/082937

§ 371 Date: Jan. 12, 2020

(30) Foreign Application Priority Data
Jan. 30, 2019 (CN) 201910093785.4

(51) Int. Cl. H05K 5/00; H01L 51/00; B32B 3/28; B32B 7/022; B32B 15/06

(52) U.S. Cl. CPC H05K 5/0017; H01L 51/0097; H04M 1/0268; B32B 7/022; B32B 15/06; B32B 3/28

(57) ABSTRACT

A flexible display screen support structure for supporting a flexible display screen is provided. The support structure includes two bending blocks, and a support sheet disposed on the two bending blocks, the support sheet includes a soft material layer and a hard material layer. The soft material layer completely covers the hard material layer, and the flexible display screen is disposed on the support sheet. The support structure provides an effect of supporting the flexible display screen and has the effect of bending performance.

### FIELD OF INVENTION

This disclosure relates to display technology, and more particularly, to a flexible display screen support structure.

### BACKGROUND OF INVENTION

Organic light-emitting diode (OLED) displays can be used in flexible display products, such as; foldable mobile phones, smart watches, and car displays, due to their advantages of being thin, flexible, foldable, etc.

Generally, a flexible OLED display screen has thin thickness and a low overall hardness. However, when the flexible OLED display screen is disposed on a foldable mobile phone, it may be touched and pressed during a user's operation. It is necessary to support the flexible OLED display screen by disposing a support material, such as a hard metal plate, below the flexible OLED display screen to prevent problems such as the flexible OLED display screen being sunken when the user presses the flexible OLED display screen, the flexible OLED display screen being broken due to excessive force, and the flexible OLED display screen not flat after repeated bending. However, since the foldable mobile phone is often bent, the support material such as the metal plate, below a bending area of the flexible OLED display screen needs to have a certain bendable property in addition to support property of the flexible OLED display screen.

### SUMMARY OF INVENTION

For a conventional support material, such as a metal plate under a bending area of a flexible OLED display screen, bendable property and support property are needed to provide for the flexible OLED display screen.

In order to solve the above-mentioned drawbacks, the disclosure provides a flexible display screen support structure for supporting a flexible display screen. The flexible display screen support structure comprises a soft material and a hard material jointly disposed, and the soft material is coated with the hard material. That provides a certain supporting effect for the flexible display screen and can meet the requirement of repeated bending to overcome the above drawbacks.

To achieve the above object, the disclosure provides a flexible display screen support structure for supporting a flexible display screen. The flexible display screen support structure comprises two bending blocks, and a support sheet disposed on the two bending blocks. The support sheet comprises a soft material layer and a hard material layer, and the soft material layer completely covers the hard material layer. The flexible display screen is disposed on the support sheet. The support sheet comprises a bending region and two non-bending regions, the hard material layer is a continuous wave-like structure, and comprises a plurality of convex portions and a plurality of concave portions, each of the convex portions and each of the concave portions are disposed staggered.

In one embodiment of the disclosure, the two non-bending regions are disposed on two sides of the bending region, and the two bending blocks are respectively disposed below the two non-bending regions.

In one embodiment of the disclosure, the support sheet further includes a supporting surface and a connecting surface, the flexible display screen is disposed on the supporting surface, and the connecting surface is connected to the bending block.

In one embodiment of the disclosure, the soft material layer is selected from a rubber material or a silica gel material.

In one embodiment of the disclosure, a thickness of the support sheet is less than 2 mm.

In one embodiment of the disclosure, a cross-sectional shape of the hard material layer is selected from the group consisting of a symmetrical wave shape, an asymmetrical wave shape, a regular wave shape, an irregular wave shape, a symmetrical jagged shape, an asymmetrical jagged shape, a regular jagged shape, an irregular jagged shape, a symmetrical square toothed wave shape, an asymmetrical square toothed wave shape, a regular square toothed wave shape, an irregular square toothed wave shape, and any combination thereof.

In one embodiment of the disclosure, the soft material layer comprises a first soft material layer and a second soft material layer laminated with each other, and the hard material layer is disposed between the first soft material layer and the second soft material layer.

In one embodiment of the disclosure, the support structure further includes a plurality of non-slip particles interval disposed on a surface of the hard material layer.

In one embodiment of the disclosure, the hard material layer is an elongated sheet-like structure made of a material having a shape memory function, and the hard material layer extends along a longitudinal direction of the flexible display screen.

To achieve the above object, the disclosure provides a flexible display screen support structure for supporting a flexible display screen. The flexible display screen support structure comprises two bending blocks, and a support sheet disposed on the two bending blocks. The support sheet comprises a soft material layer and a hard material layer, and the soft material layer completely covers the hard material layer. The flexible display screen is disposed on the support sheet.

In one embodiment of the disclosure, the support sheet comprises a bending region and two non-bending regions, the hard material layer is a continuous wave-like structure, the two non-bending regions are disposed on two sides of the bending region, and the two bending blocks are respectively disposed below the two non-bending regions.

In one embodiment of the disclosure, the support sheet further includes a supporting surface and a connecting surface, the flexible display screen is disposed on the supporting surface, and the connecting surface is connected to the bending block.

In one embodiment of the disclosure, the soft material layer is selected from a rubber material or a silica gel material.

In one embodiment of the disclosure, the hard material layer is a continuous wave-like structure, and comprises a plurality of convex portions and a plurality of concave portions, each of the convex portions and each of the concave portions are disposed staggered.

In one embodiment of the disclosure, a thickness of the support sheet is less than 2 mm.

In one embodiment of the disclosure, a cross-sectional shape of the hard material layer is selected from the group consisting of a symmetrical wave shape, an asymmetrical wave shape, a regular wave shape, an irregular wave shape, a symmetrical jagged shape, an asymmetrical jagged shape, a regular jagged shape, an irregular jagged shape, a symmetrical square toothed wave shape, an asymmetrical square toothed wave shape, a regular square toothed wave shape, an irregular square toothed wave shape, and any combination thereof.

In one embodiment of the disclosure, the soft material layer comprises a first soft material layer and a second soft material layer laminated with each other, and the hard material layer is disposed between the first soft material layer and the second soft material layer.

In one embodiment of the disclosure, the support structure further includes a plurality of non-slip particles interval disposed on a surface of the hard material layer.

In one embodiment of the disclosure, the hard material layer is an elongated sheet-like structure made of a material having a shape memory function, and the hard material layer extends along a longitudinal direction of the flexible display screen.

The disclosure further provides a flexible display screen support structure for supporting a flexible display screen. The flexible display screen support structure comprises two bending blocks and a support sheet disposed on the two bending blocks. The support sheet comprises a soft material layer and a hard material layer, and the soft material layer completely covers the hard material layer. The flexible display screen is disposed on the support sheet. The support sheet comprises a bending region and two non-bending regions, the hard material layer is a continuous wave-like structure, and the hard material layer comprises a plurality of convex portions and a plurality of concave portions, each of the convex portions and each of the concave portions are disposed staggered. Spacing between two of the convex portions adjacent to each other in the bending region is greater than spacing between two of the convex portions adjacent to each other in the non-bending region.

The technical effects are as follows. The flexible display screen support structure provided by the present disclosure is a support structure composed of a hard material (mainly for supporting) and a soft material (mainly for increasing surface flatness). The soft material is coated with the hard material, so that the support structure provides a certain supporting effect for the flexible display screen. The support structure of the disclosure prevents the flexible display screen from being depressed, being broken when subjected to external forces, or being rugged after repeatedly bending the flexible display screen during the operation process of the flexible display screen of the user. Meanwhile, the support structure provides a bending property that can be matched with the flexible display screen. That ensures that a foldable touch display device does not require excessive external force when bending, and the support structure is not easily plastically deformed or even broken after repeated bending.

### DESCRIPTION OF DRAWINGS

FIG. 1 is an exploded schematic diagram of a flexible display screen support structure according to a first embodiment of the disclosure.

FIG. 2 is a schematic diagram of the flexible display screen support structure in an unfolded state of the disclosure.

FIG. 3 is a schematic diagram of the flexible display screen support structure in a bent state of the disclosure.

FIG. 4 is a cross-sectional diagram of a support sheet of the flexible display screen support structure according to a second embodiment of the disclosure.

FIG. 5 is a cross-sectional diagram of the support sheet of the flexible display screen support structure according to a third embodiment of the disclosure.

FIG. 6 is a cross-sectional diagram of the support sheet of the flexible display screen support structure according to a fourth embodiment of the disclosure.

FIG. 7 is a cross-sectional diagram of the support sheet of the flexible display screen support structure according to a fifth embodiment of the disclosure.

FIG. 8 is a cross-sectional diagram of the support sheet of the flexible display screen support structure according to a sixth embodiment of the disclosure.

### DETAILED DESCRIPTION OF PREFERRED EMBODIMENTS

This description of the exemplary embodiments is intended to be read in connection with the accompanying drawings, which are to be considered part of the entire written description.

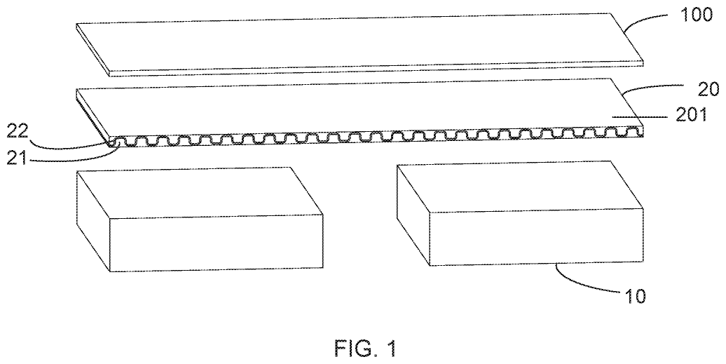

Referring to FIG. 1, an exploded schematic diagram of a flexible display screen support structure according to a first embodiment of the disclosure is shown. In the first embodiment of the present disclosure, the flexible display screen support structure is used to support a flexible display screen 100. The support structure includes two bending blocks 10, and a support sheet 20 disposed on the two bending blocks 10. The support sheet 20 comprises a soft material layer 21 and a hard material layer 22, and the hard material layer 22 is completely coated by the soft material layer 21. The flexible display screen 100 is disposed on the support sheet 20.

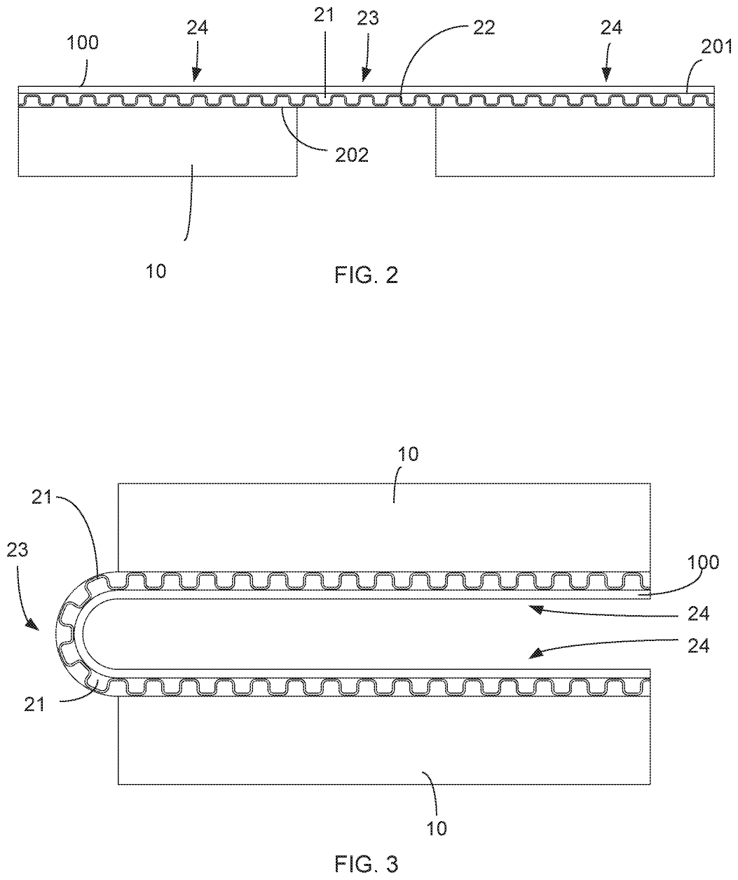

The support sheet 20 has a thickness of less than 2 mm. The support sheet 20 further includes a supporting surface 201 and a connecting surface 202 (see FIG. 2). The flexible display screen 100 is disposed on the supporting surface 201, and the connecting surface 202 is connected to the bending block 10. The support sheet 20 further includes a bending region 23 and two non-bending regions 24 (see FIG. 3). The two non-bending regions 24 are disposed on two sides of the bending region 23, and the two bending blocks 10 are respectively disposed below the two non-bending regions 24. It should be noted that a longitudinal direction of the hard material layer 22 and a longitudinal direction of the soft material layer 21 and a longitudinal direction of the flexible display screen 100 are identical. The hard material layer 22 can be warped or unfolded in the longitudinal direction of the flexible display screen 100 to match the flexibility of the flexible display screen 100.

The soft material layer 21 is selected from a rubber material, a silica gel material, or a flexible material, such as rubber, silica gel or the like. The hard material layer 22 is an elongated sheet-like structure made of a material having a shape memory function, and the hard material layer 22 extends along the longitudinal direction of the flexible display screen 100. The disclosure is not limited to the material from which the hard material layer 22 is formed, as long as it is a hard material that can provide hard support for the flexible display screen 100, such as metal, plastic, polymer, and the like. For example, the material of the hard material layer 22 may be memory alloy materials such as Ag—Cd, Cu—Zn, Cu—Zn—Sn, Cu—Zn—Si, Cu—Sn, Cu—Zn—Ga, In—Ti, Au—Cu—Zn, Ni—Al, Fe—Pt, Ti—Ni, Ti—Ni—Pd, Ti—Nb, U—Nb or Fe—Mn—Si. Preferably, the hard material layer 22 is made of manganese steel or other spring materials for manufacturing springs for reduction cost.

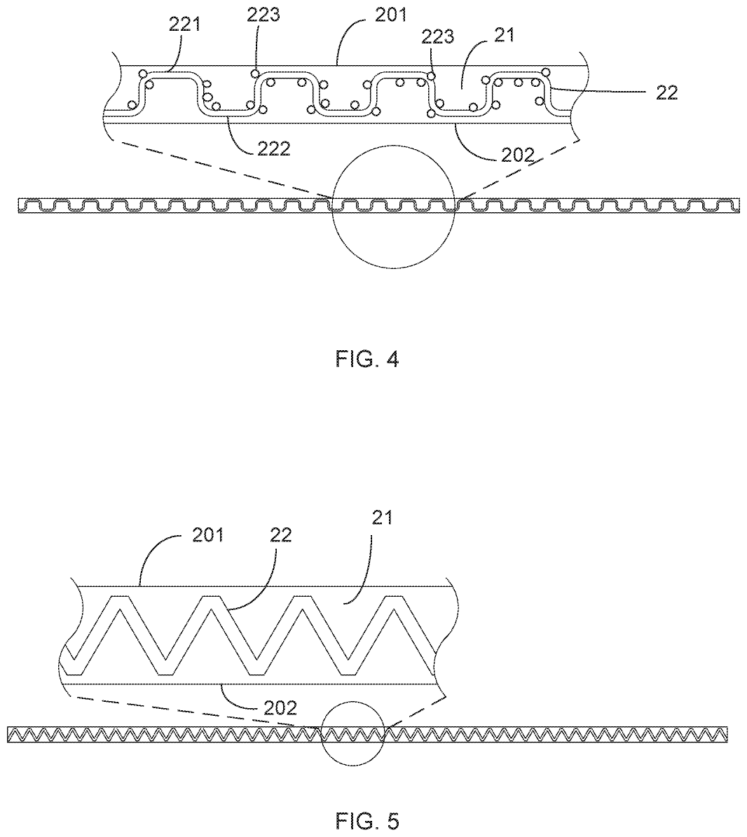

Referring to FIG. 2, a schematic diagram of the flexible display screen support structure in an unfolded state of the disclosure is shown. The hard material layer 22 is a continuous wave-like structure, and comprises a plurality of convex portions 221 and a plurality of concave portions 222 (shown in FIG. 4), each of the convex portions 221 and each of the concave portions 222 are disposed staggered. The hard material layer 22 and the soft material layer 21 of the support sheet 20 are in an unfolded state, the two bent blocks 10 are disposed on the same plane. The flexible display screen 100 is also in an unfolded state. The function of the soft material layer 21 is to increase the flatness of the entire surface of the support structure, and the support surface 201 is attached to the flexible display screen 100 to restore the flatness of the flexible display screen 100 after bending. While the hard material layer 22 is in the unfolded state, a support rigidity of the support structure can be improved, and the flexible display screen 100 can be prevented from being too soft and being sunken by an external force or being damaged due to excessive deformation.

Referring to FIG. 3, a schematic diagram of the flexible display screen support structure in a bent state of the disclosure is shown. The bending block 10 at both ends is bent by an external force (hand force), so that the support structure and the flexible display screen 100 are bent to become the bent state. When the support surface 201 of the support structure is curled to curl the flexible display screen 100, the soft material layer 21 is compressed. The function of the hard material layer 22 is to provide rigid support for the flexible display screen 100, and the hard material layer 22 is configured to form a wavy sheet-like structure to improve its bendability. When a foldable device (not shown) is bent, the wavy sheet-like structure can reduce the deformation amount of the hard material layer 22 of the bending region 23 compared to a conventional support structure having the same overall thickness, and is advantageous for the recovery capability and service life of the support structure during repeated bending. At the same time, the wavy hard material layer 22 reduces the mutual extrusion of the materials in the bending region 23, thereby reducing the external force required for the bending the supporting structure, and improving the comfort and labor saving of the user as folding the foldable device. Meanwhile, due to the thickness of the flexible display and the support structure, the respective bending radius will be different when bending. Therefore, the flexible display screen 100 and the supporting structure which are attached after bending will be slightly displaced. The soft material layer 21 of the support surface 201 of the support structure can compensate for this slight displacement difference by elastic deformation.

Finally, both ends of the bending block 10 is reset and flattened by the external force (hand force) or by the release of the external force, and the flexible display screen 100 and the support structure are reset to the unfolded state. This is a transition process between the unfolded state and the bent state of the present embodiment.

According to an embodiment of the disclosure, the support structure further includes a plurality of non-slip particles 223 (see FIG. 4) interval disposed on a surface of the hard material layer. The roughness of the surface of the hard material layer 22 is increased by a surface treatment such as plasma treatment or the like. For example, a granular surface or a rough surface is formed, and connection strength between the hard material layer 22 and the soft material layer 21 is increased.

In different embodiments, the hard material layer 22, the soft material layer 21, and the bent block 10 are integrally injection molded. In different embodiments, the hard material layer 22 is formed inside the soft material layer 10, that is, the soft material layer 21 is a double-layer structure provided in a layered manner. Namely, the soft material layer 21 includes a first soft material layer (not shown) and a second soft material layer (not shown), the hard material layer 22 is disposed between the first soft material layer and the second soft material layer.

According to an embodiment of the disclosure, a cross-sectional shape of the hard material layer 22 is selected from the group consisting of a symmetrical wave shape, an asymmetrical wave shape, a regular wave shape, an irregular wave shape, a symmetrical jagged shape, an asymmetrical jagged shape, a regular jagged shape, an irregular jagged shape, a symmetrical square toothed wave shape, an asymmetrical square toothed wave shape, a regular square toothed wave shape, an irregular square toothed wave shape, and any combination thereof. Referring to FIGS. 4-8, cross-sectional diagrams of the support sheet of the flexible display screen support structure according to a second embodiment to a sixth of embodiment the disclosure are shown.

In the support sheet of the flexible display screen support structure as shown in FIG. 4, the cross section of the hard material layer 22 is a uniform square shape and is coated in the soft material layer 21.

In the support sheet of the flexible display screen support structure as shown in FIG. 5, the cross section of the hard material layer 22 is a uniform zigzag shape and is coated in the soft material layer 21.

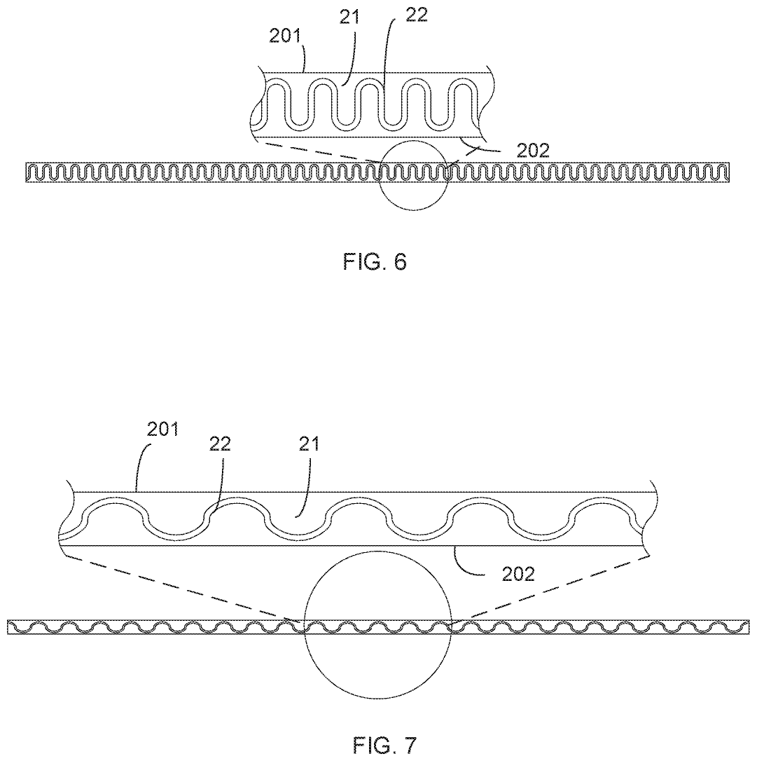

In the support sheet of the flexible display screen support structure as shown in FIG. 6, the cross section of the hard material layer 22 is a uniform circular wavy shape and is coated in the soft material layer 21.

In the support sheet of the flexible display screen support structure as shown in FIG. 7, the cross section of the hard material layer 22 is a uniform elliptical wavy shape and is coated in the soft material layer 21.

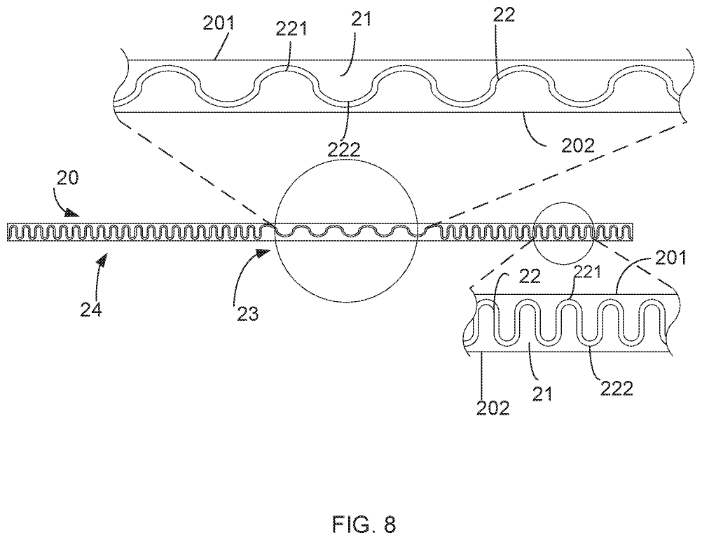

In the support sheet of the flexible display screen support structure as shown in FIG. 8, the cross section of the hard material layer 22 is a non-uniform wavy shape and is coated in the soft material layer 21. Each of the convex portions 221 is interlaced with each of the concave portions 222. A spacing between two of the convex portions 221 adjacent to each other in the bending region 23 is greater than a spacing between two of the convex portions 221 adjacent to each other in the non-bending region 24. That is, a spacing between adjacent concave portions 222 in the bending region 23 is also greater than a spacing between adjacent concave portions 222 in the non-bending region 24. Furthermore, the wave density of the above-mentioned wavy sharp is different in different regions of the hard material layer 22. For example, in the bending region 23, the hard material layer 22 has a relatively loose undulating wavy shape, so that the bending portion 23 of the supporting structure is easier to be bent and the bending property of the supporting structure is improved. Besides, in the non-bending region 24, the hard material layer 22 has a relatively dense undulating wavy shape, which makes it provides a more supportive effect for supporting the flexible display screen 100. As mentioned above, it can be seen that the wave density of the wavy shape of the hard material layer 22 in different regions (for example, in the bending region 23 and the non-bending region 24, respectively) can be adjusted according to the use requirements. It can be a denser wavy shape or be a looser wavy shape. It is also can be that the hard material layer 22 is partially densely wavy shape, and the hard material layer 22 is partially loosely wavy shape. Moreover, the shape of the cross section of the hard material layer 22 may be the same or different in different regions (for example, in the bending region 23 and the non-bending region 24, respectively).

The flexible display screen support structure provided by the present disclosure is a support structure composed of a hard material (mainly for supporting) and a soft material (mainly for increasing surface flatness). The soft material is coated with the hard material, so that the support structure provides a certain supporting effect for the flexible display screen. The support structure of the disclosure prevents the flexible display screen from being depressed, being broken when subjected to external forces, or being rugged after repeatedly bending the flexible display screen during the operation process of the flexible display screen of the user. Meanwhile, the support structure provides a bending property that can be matched with the flexible display screen. That ensures that a foldable touch display device does not require excessive external force when bending, and the support structure is not easily plastically deformed or even broken after repeated bending. This disclosure has been described with preferred embodiments thereof, and it is understood that many changes and modifications to the described embodiment can be carried out without departing from the scope and the spirit of the invention.

1. A flexible display screen support structure for supporting a flexible display screen, comprising:
two bending blocks; and
a support sheet disposed on the two bending blocks, the support sheet comprising a soft material layer and a hard material layer, and the soft material layer completely covering the hard material layer, wherein the flexible display screen is disposed on the support sheet;
wherein the support sheet comprises a bending region and two non-bending regions, the hard material layer is a continuous wave-like structure, and comprises a plurality of convex portions and a plurality of concave portions, each of the convex portions and each of the concave portions are disposed staggered.

2. The flexible display screen support structure according to claim 1, wherein the two non-bending regions are disposed on two sides of the bending region, and the two bending blocks are respectively disposed below the two non-bending regions.

3. The flexible display screen support structure according to claim 1, wherein the support sheet further includes a supporting surface and a connecting surface, the flexible display screen is disposed on the supporting surface, and the connecting surface is connected to the bending block.

4. The flexible display screen support structure according to claim 1, wherein the soft material layer is selected from a rubber material or a silica gel material.

5. (canceled)

6. The flexible display screen support structure according to claim 1, wherein a thickness of the support sheet is less than 2 mm.

7. The flexible display screen support structure according to claim 1, wherein a cross-sectional shape of the hard material layer is selected from the group consisting of a symmetrical wave shape, an asymmetrical wave shape, a regular wave shape, an irregular wave shape, a symmetrical jagged shape, an asymmetrical jagged shape, a regular jagged shape, an irregular jagged shape, a symmetrical square toothed wave shape, an asymmetrical square toothed wave shape, a regular square toothed wave shape, an irregular square toothed wave shape, and any combination thereof.

8. The flexible display screen support structure according to claim 1, wherein the soft material layer comprises a first soft material layer and a second soft material layer laminated with each other, and the hard material layer is disposed between the first soft material layer and the second soft material layer.

9. The flexible display screen support structure according to claim 1, wherein the support structure further includes a plurality of non-slip particles interval disposed on a surface of the hard material layer.

10. A flexible display screen support structure for supporting a flexible display screen, comprising:
two bending blocks; and
a support sheet disposed on the two bending blocks, the support sheet comprising a soft material layer and a hard material layer, and the soft material layer completely covering the hard material layer, wherein the flexible display screen is disposed on the support sheet.

11. The flexible display screen support structure according to claim 10, wherein the support sheet comprises a bending region and two non-bending regions, the hard material layer is a continuous wave-like structure, the two non-bending regions are disposed on two sides of the bending region, and the two bending blocks are respectively disposed below the two non-bending regions.

12. The flexible display screen support structure according to claim 10, wherein the support sheet further includes a supporting surface and a connecting surface, the flexible display screen is disposed on the supporting surface, and the connecting surface is connected to the bending block.

13. The flexible display screen support structure according to claim 10, wherein the soft material layer is selected from a rubber material or a silica gel material.

14. The flexible display screen support structure according to claim 10, wherein the hard material layer is a continuous wave-like structure, and comprises a plurality of convex portions and a plurality of concave portions, each of the convex portions and each of the concave portions are disposed staggered.

15. The flexible display screen support structure according to claim 10, wherein a thickness of the support sheet is less than 2 mm.

16. The flexible display screen support structure according to claim 10, wherein a cross-sectional shape of the hard material layer is selected from the group consisting of a symmetrical wave shape, an asymmetrical wave shape, a regular wave shape, an irregular wave shape, a symmetrical jagged shape, an asymmetrical jagged shape, a regular jagged shape, an irregular jagged shape, a symmetrical square toothed wave shape, an asymmetrical square toothed wave shape, a regular square toothed wave shape, an irregular square toothed wave shape, and any combination thereof.

17. The flexible display screen support structure according to claim 10, wherein the soft material layer comprises a first soft material layer and a second soft material layer laminated with each other, and the hard material layer is disposed between the first soft material layer and the second soft material layer.

18. The flexible display screen support structure according to claim 10, wherein the support structure further includes a plurality of non-slip particles interval disposed on a surface of the hard material layer.

19. A flexible display screen support structure for supporting a flexible display screen, comprising:
two bending blocks; and
a support sheet disposed on the two bending blocks, the support sheet comprising a soft material layer and a hard material layer, and the soft material layer completely covering the hard material layer, wherein the flexible display screen is disposed on the support sheet;
wherein the support sheet comprises a bending region and two non-bending regions, the hard material layer is a continuous wave-like structure, and comprises a plurality of convex portions and a plurality of concave portions, each of the convex portions and each of the concave portions are disposed staggered, and wherein a spacing between two of the convex portions adjacent to each other in the bending region is greater than a spacing between two of the convex portions adjacent to each other in the non-bending region.
